(19) United States
(12) Patent Application Publication
(10) Pub. No.: US 2023/0041619 A1
(43) Pub. Date: Feb. 9, 2023

(54) ACCOMMODATION CONTAINER AND CHARGING METHOD FOR SUBSTRATE-SHAPED SENSOR

(71) Applicant: Tokyo Electron Limited, Tokyo (JP)

(72) Inventor: Yuuji AKIDUKI, Miyagi (JP)

(21) Appl. No.: 17/817,091

(22) Filed: Aug. 3, 2022

(30) Foreign Application Priority Data
Aug. 4, 2021 (JP) 2021-128408
Jun. 24, 2022 (JP) 2022-101916

(51) Int. Cl. H01L 21/677; H02J 7/00; H01L 21/67

(52) U.S. Cl. CPC H01L 21/67769; H02J 7/0045; H01L 21/67242; H01L 21/67167; H01L 21/67772

(57) ABSTRACT

With respect to an accommodation container that accommodates a substrate-shaped sensor, the accommodation container includes a container body that has an opening, a support that is disposed inside the container body and configured to support the substrate-shaped sensor, a contact pin that is disposed inside the container body and configured to come into contact with a terminal portion of the substrate-shaped sensor, a driving mechanism that is disposed inside the container body and configured to drive the contact pin, a rotation shaft member that drives the driving mechanism from an outside of the container body, a jack that is disposed outside the container body and electrically connected to the contact pin, and a lid that is configured to close the opening of the container body.

### CROSS-REFERENCE TO RELATED APPLICATIONS

This patent application is based on and claims priority to Japanese Patent Application No. 2021-128408, filed on Aug. 4, 2021, and Japanese Patent Application No. 2022-101916, filed on Jun. 24, 2022, the entire contents of which are incorporated herein by reference.

### TECHNICAL FIELD

The present disclosure relates to an accommodation container and a charging method for a substrate-shaped sensor.

### BACKGROUND

A semiconductor processing system that transfers a substrate-shaped sensor by using a transfer device for transferring a substrate such as a wafer, is disclosed.

Patent Document 1 and Patent Document 2 disclose a wireless substrate-shaped sensor that is taken out from an accommodation unit and that is moved to a reference target by a robot.

It is desired to charge a substrate-shaped sensor in a state where the substrate-shaped sensor is accommodated in the accommodation container. Further, it is desired that the accommodation container accommodating the substrate-shaped sensor is configured to be transferable by a transfer device such as an overhead hoist transport (OHT) or a person guided vehicle (PGV).

In one aspect, the present disclosure provides an accommodation container that accommodates a substrate-shaped sensor and a charging method for a substrate-shaped sensor.

### RELATED ART DOCUMENT

### Patent Document

[Patent Document 1] Japanese National Publication of International Patent Application No. 2005-521926
[Patent Document 2] Japanese Patent Application Publication No. 2005-202933

### SUMMARY

According to one aspect of the present disclosure, with respect to an accommodation container that accommodates a substrate-shaped sensor, the accommodation container includes a container body that has an opening, a support that is disposed inside the container body and configured to support the substrate-shaped sensor, a contact pin that is disposed inside the container body and configured to come into contact with a terminal portion of the substrate-shaped sensor, a driving mechanism that is disposed inside the container body and configured to drive the contact pin, a rotation shaft member that drives the driving mechanism from outside the container body, a jack that is disposed outside the container body and electrically connected to the contact pin, and a lid that is configured to close the opening of the container body.

### BRIEF DESCRIPTION OF THE DRAWINGS

FIG. 1 is a view illustrating an example of an overall configuration of a semiconductor manufacturing apparatus according to an embodiment;

FIG. 2 is an example of a partial sectional view of an accommodation container as viewed from a side;

FIG. 3 is an example of a front view of the accommodation container with a lid being removed.

FIG. 4 is an example of a partial sectional view of the accommodation container as viewed from above;

FIG. 5 is an example of a back view of the accommodation container;

FIG. 6 is an example of a schematic view illustrating a state where a substrate-shaped sensor accommodated in the accommodation container is charged;

FIG. 7 is an example of a schematic view illustrating a state where the substrate-shaped sensor accommodated in the accommodation container is taken out;

FIG. 8 is a configuration block diagram of the substrate-shaped sensor accommodated in the accommodation container; and

FIG. 9 is another example of a partial sectional view of the accommodation container as viewed from the side.

### DETAILED DESCRIPTION OF EMBODIMENTS

Hereinafter, embodiments for implementing the present disclosure will be described with reference to the drawings. In the respective drawings, the same components will be denoted by the same reference numerals, and overlapping descriptions thereof may be appropriately omitted.

(Overall Configuration of Semiconductor Manufacturing Apparatus)

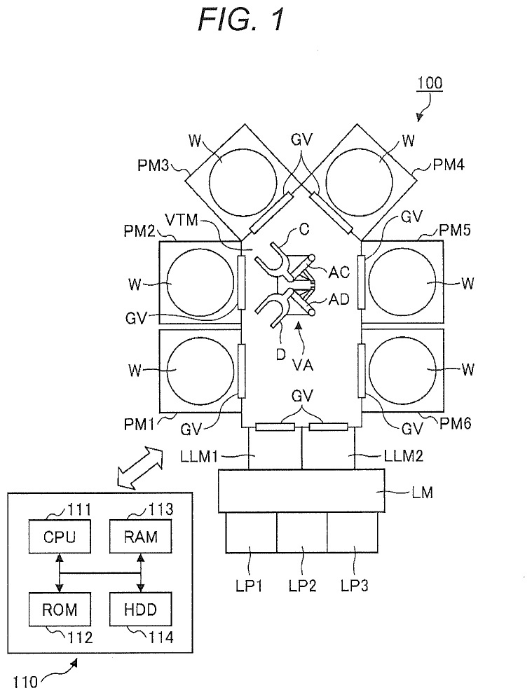

First, an example of a longitudinal sectional configuration of a semiconductor manufacturing apparatus 100 according to an embodiment of the present invention will be described with reference to FIG. 1. The semiconductor manufacturing apparatus 100 illustrated in FIG. 1 is an apparatus having a cluster structure (multi-chamber type), and a transfer chamber VTM and a substrate processing chamber PM are an example of a vacuum device.

The semiconductor manufacturing apparatus 100 of FIG. 1 includes substrate processing chambers PM1 to PM6 (process modules), a transfer chamber VTM (vacuum transfer module), load-lock chambers LLM1 and LLM2 (load lock module), a loader module LM (loader module), and load ports LP1 to LP3 (load port).

The semiconductor manufacturing apparatus 100 is controlled by a controller 110 to perform a predetermined process on a semiconductor wafer W (hereinafter, also referred to as a “wafer W”), which is an example of a substrate.

The substrate processing chambers PM1 to PM6 are disposed adjacent to the transfer chamber VTM. The substrate processing chambers PM1 to PM6 are also collectively referred to as substrate processing chambers PM. The substrate processing chambers PM1 to PM6 communicate with the transfer chamber VTM by opening and closing gate valves GV. The substrate processing chambers PM1 to PM6 are decompressed to a predetermined vacuum atmosphere, and the wafers W are subjected to processes such as an etching process, a film formation process, a cleaning process, and an asking process inside the substrate processing chambers PM1 to PM6.

A transfer device VA for transferring the wafer W is disposed inside the transfer chamber VTM. The transfer device VA includes two robot arms AC and AD that are bendable and rotatable. Picks C and D are respectively attached to distal end portions of the robot arms AC and AD. The transfer device VA can hold the wafer W in each of the picks C and D, and performs carrying-in and carrying-out of the wafer W between the substrate processing chambers PM1 to PM6 and the transfer chamber VTM according to opening and closing of the gate valves GV. Further, the transfer device VA performs carrying-in and carrying-out of the wafer W between the transfer chamber VTM and the load-lock chambers LLM1 and LLM2 according to the opening and closing of the gate valves GV.

The load-lock chambers LLM1 and LLM2 are provided between the transfer chamber VTM and the loader module LM. The load-lock chambers LLM1 and LLM2 switch between the ambient air atmosphere and the vacuum atmosphere to transfer the wafer W from the loader module LM on the ambient air side to the transfer chamber VTM on the vacuum side, or transfer the wafer W from the transfer chamber VTM on the vacuum side to the loader module LM on the ambient air side.

The loader module LM includes load ports LP1 to LP3. For example, a front opening unified pod (FOUP) in which 25 wafers W are accommodated or an empty FOUP is placed in the load ports LP1 to LP3. The loader module LM carries the wafer W, carried out from the FOUPs inside the load ports LP1 to LP3, in either one of the load-lock chambers LLM1 and LLM2, and carries the wafer W, carried out from either one of the load-lock chambers LLM1 and LLM2, in the FOUP.

The controller 110 includes a central processing unit (CPU) 111, a read only memory (ROM) 112, a random access memory (RAM) 113, and a hard disk drive (HDD) 114. The storage area is not limited to the HDD 114, and the controller 110 may include another storage area such as a solid state drive (SSD). The storage areas such as the HDD 114 and the RAM 113 store a recipe in which process procedures, process conditions, transfer conditions, and the like are set.

The CPU 111 controls the process of the wafer W in the substrate processing chamber PM and controls the transfer of the wafer W according to the recipe. Further, the CPU 111 controls process processing such as gas introduction and exhaust control, measurement of particles, and the like according to the present embodiment. The HDD 114 and the RAM 113 may store, for example, programs for performing a substrate transfer process, a cleaning process, an exhaust control process, and the like. These programs may be stored in a recording medium or may be provided from an external device through a network.

The number of substrate processing chambers PM, the number of the load-lock chambers LLM, and the number of the load ports LP are not limited to the numbers illustrated in the present embodiment, and each of the numbers may be one or more.

With this configuration, the semiconductor manufacturing apparatus 100 can attach the FOUP in which the wafers W are accommodated or the empty FOUP to the load ports LP1 to LP3. Further, the semiconductor manufacturing apparatus 100 can take out, from the FOUP, the unprocessed wafer W accommodated in the FOUP, and transfer the wafer W to each of the substrate processing chambers PM1 to PM6 via the loader module LM, the load-lock chambers LLM1 and LLM2, and the transfer chamber VTM. Further, the semiconductor manufacturing apparatus 100 can perform a desired process on the wafer W in each of the substrate processing chambers PM1 to PM6. Further, the semiconductor manufacturing apparatus 100 can take out the processed wafer W from each of the substrate processing chambers PM1 to PM6, and can accommodate the wafer W in the FOUP via the transfer chamber VTM, the load-lock chambers LLM1 and LLM2, and the loader module LM.

<Accommodation Container>

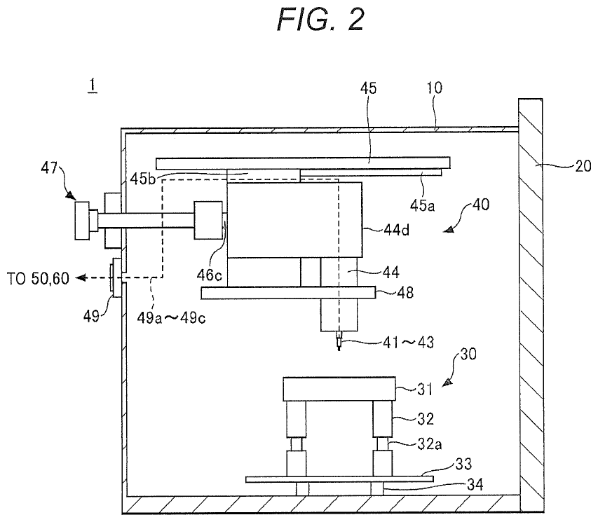

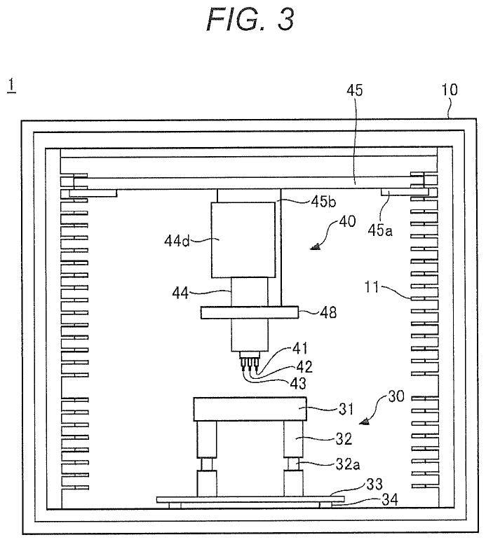

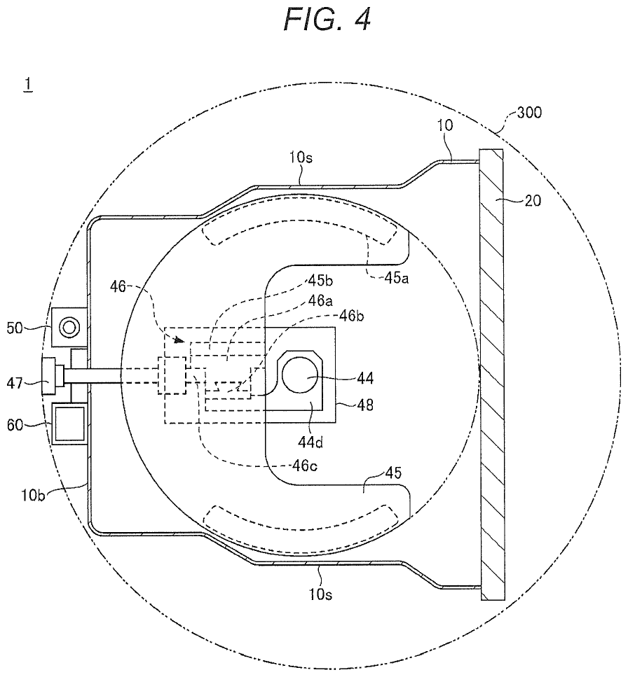

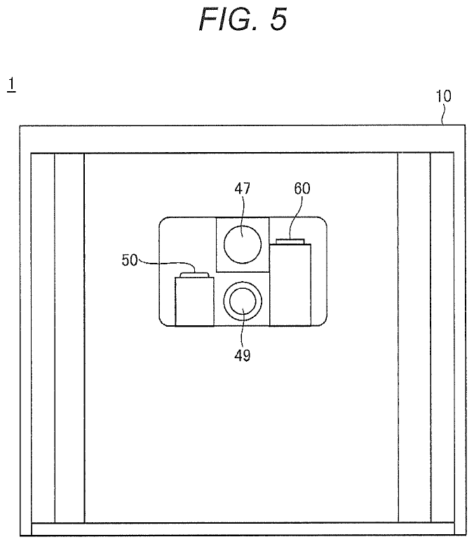

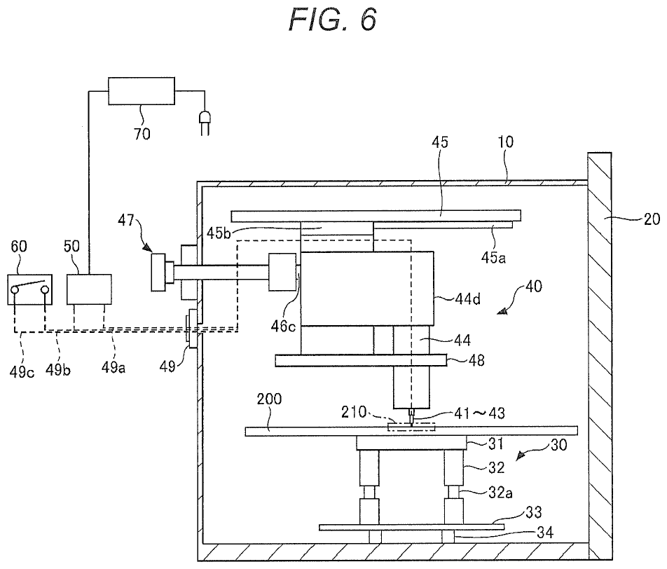

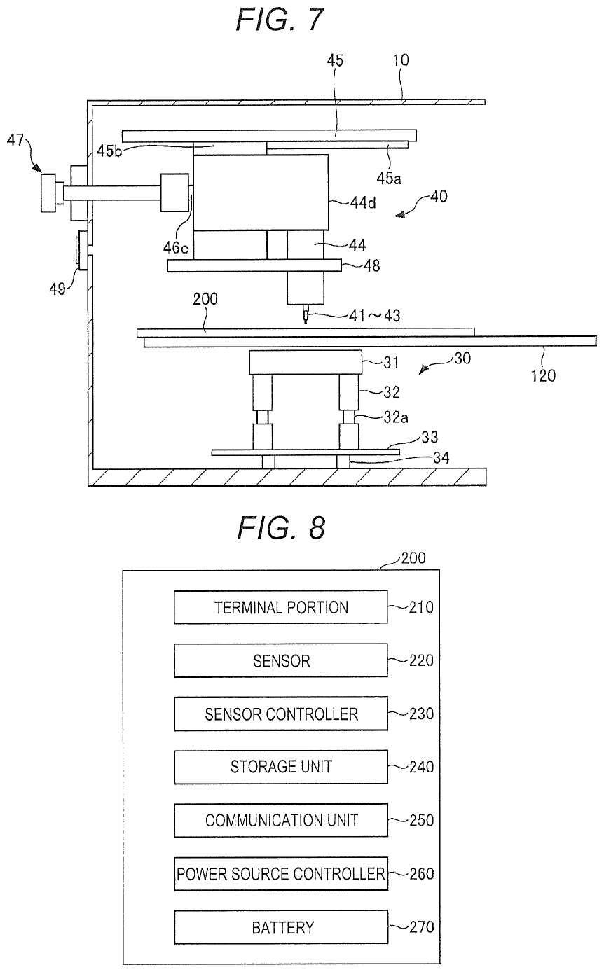

Next, an accommodation container 1 according to the present embodiment will be further described with reference to FIGS. 2 to 7. FIG. 2 is an example of a partial sectional view of the accommodation container 1 as viewed from a side. FIG. 3 is an example of a front view of the accommodation container 1 with a lid 20 being removed. FIG. 4 is an example of a partial sectional view of the accommodation container 1 as viewed from above. FIG. 5 is an example of a back view of the accommodation container 1. FIG. 6 is an example of a schematic view illustrating a state where a substrate-shaped sensor 200 accommodated in the accommodation container 1 is charged. FIG. 7 is an example of a schematic view illustrating a state where the substrate-shaped sensor 200 accommodated in the accommodation container 1 is taken out. In the following description, an opening side (a side connected to the load ports LP1 to LP3) of the accommodation container 1 will be described as a front side of the accommodation container 1, and a rear side of the accommodation container 1 as viewed from the opening side will be described as a rear side of the accommodation container 1. A DC jack 50 and a switch 60 in FIG. 6 schematically illustrate a circuit configuration, and positions are not limited to the positions in FIG. 6. Further, in FIGS. 3, 4, 5, and 7, illustrations of wirings 49a to 49c are appropriately omitted. Further, FIG. 7 illustrates an example of a state where the accommodation container 1 is attached to the load port LP (not illustrated in FIG. 7), the lid 20 (not illustrated in FIG. 7) is removed by the load port LP, and the substrate-shaped sensor 200 is taken out from the accommodation container 1 by an end effector 120 of the transfer device (not illustrated) of the loader module LM.

The accommodation container 1 includes a container body 10 configured to accommodate the substrate-shaped sensor 200, and the lid 20 that detachably opens and closes the opening of the container body 10 on the front side.

Here, the accommodation container 1 accommodating the substrate-shaped sensor 200 has the same attachment shape as that of the FOUP. Accordingly, the accommodation container 1 is configured to be attached to the load ports LP1 to LP3. Further, the load ports LP1 to LP3 can open and close the lid 20 (see FIG. 2) of the accommodation container 1.

Further, as illustrated in FIGS. 6 and 7, the substrate-shaped sensor 200 has, for example, a disk having the same diameter as that of the wafer W. Further, the substrate-shaped sensor 200 includes various sensors 220 (see FIG. 8 to be described later, for example, a temperature sensor, an electrostatic capacitance sensor, a humidity sensor, an acceleration sensor, an image sensor, and the like) provided on the disk. Accordingly, the transfer device VA of the transfer chamber VTM and the transfer device (not illustrated) of the loader module LM can transfer the substrate-shaped sensor 200 in the same manner as the wafer W. Further, the substrate-shaped sensor 200 can be placed on a stage (not illustrated) of each of the substrate processing chambers PM1 to PM6 and a stage (not illustrated) of each of the load-lock chambers LLM1 and LLM2 in the same manner as the wafer W.

With this configuration, the semiconductor manufacturing apparatus 100 can attach the accommodation container 1 accommodating the substrate-shaped sensor 200 to the load ports LP1 to LP3. Further, the semiconductor manufacturing apparatus 100 can take out the substrate-shaped sensor 200 accommodated in the accommodation container 1 from the accommodation container 1, and transfer the substrate-shaped sensor 200 to a desired measurement position (for example, each of the substrate processing chambers PM1 to PM6) via the loader module LM, the load-lock chambers LLM1 and LLM2, and the transfer chamber VTM. Further, the semiconductor manufacturing apparatus 100 can accommodate the substrate-shaped sensor 200 in the accommodation container 1 from a desired measurement position via the transfer chamber VTM, the load-lock chambers LLM1 and LLM2, and the loader module LM. Further, the substrate-shaped sensor 200 can detect various types of information (temperature, capacitance, humidity, acceleration, image, and the like) by using the sensor 220 (see FIG. 8 to be described later) during the transfer and at a desired detection position.

The container body 10 has a bottom wall, a ceiling wall, a pair of side surface sidewalls 10s, and a rear surface sidewall 10b, and is formed as a front open box having an opening on the front side (a front opening). The bottom wall, the ceiling wall, and the pair of side surface sidewalls 10s form the front opening to which the lid 20 is attached. The rear surface sidewall 10b is provided on a side opposite to the front opening to which the lid 20 is attached. The front opening of the container body 10 has the same shape as the front opening of the standardized FOUP that accommodates the wafer W. As a material forming the container body 10, for example, an engineering plastic such as polycarbonate (PC) or polybutylene terephthalate (PBT) can be used. Further, it is more preferable to use a low hygroscopic material for the container body 10.

A pair of left and right teeth 11 that are horizontally formed ledge-shaped protrusions, are provided on the inner side of the side surface sidewall 10s of the container body 10. The substrate-shaped sensor 200 is placed on the pair of left and right teeth 11. That is, the pair of left and right teeth 11 horizontally support left and right peripheral edges of a lower surface of the substrate-shaped sensor 200.

Further, the teeth 11 may be provided in multiple stages in a height direction. The teeth 11 formed in multiple stages in the height direction are formed at the same pitch as that of the standardized FOUPs that accommodate the wafer W. Accordingly, the transfer device (not illustrated) of the loader module LM can take out the substrate-shaped sensor 200 from the accommodation container 1 in the same operation as the operation of taking out the wafer W from the FOUP. Further, as the container body 10 of the accommodation container 1, a FOUP container body can be used. In the example illustrated in FIG. 3, a case in which the substrate-shaped sensor 200 is to be placed on an eighth pair of teeth 11 from the bottom will be described.

Further, in the teeth 11 of the stage that supports the substrate-shaped sensor 200 (the eighth stage from the bottom in the example illustrated in FIG. 3) among the teeth 11 formed in multiple stages, the teeth 11 of the next stage may be formed at twice the pitch of the other stages. In other words, among the teeth 11 formed in multiple stages at the same pitch, teeth corresponding to teeth of the next stage (the ninth stage from the bottom) of the stage that supports the substrate-shaped sensor 200 are removed. Accordingly, even if the substrate-shaped sensor 200 is formed thicker than the wafer W, the substrate-shaped sensor 200 can be accommodated in the container body 10. Further, when the substrate-shaped sensor 200 is taken out from the accommodation container 1, even if the substrate-shaped sensor 200 is lifted by an end effector 120 of the transfer device (not illustrated) of the loader module LM, the upper surface of the substrate-shaped sensor 200 can be prevented from touching the lower surface of the teeth 11 of the next stage.

A rear retainer (not illustrated) that supports substantially horizontally the rear peripheral edge of the lower surface of the substrate-shaped sensor 200 may be provided on the inner side of the rear surface sidewall of the container body 10. Further, a front retainer (not illustrated) that supports substantially horizontally the front peripheral edge of the lower surface of the substrate-shaped sensor 200 may be provided on the back surface of the lid 20.

Further, similar to the FOUP, a handle (not illustrated) that is gripped by an operator in transferring of the accommodation container 1 may be provided on the outer side of the side surface sidewall 10s of the container body 10. Further, similar to the FOUP, a rail (not illustrated) that serves as a guide for transferring the accommodation container 1 may be provided on the outer side of the side surface sidewall 10s of the container body 10. Further, similar to the FOUP, a groove (not illustrated) for positioning the accommodation container 1 when the accommodation container 1 is attached to the load ports LP1 to LP3 may be provided on the outer side of the bottom wall of the container body 10. Further, a flange (not illustrated) for lifting and transferring the accommodation container 1 may be provided on the upper surface of the container body 10.

The lid 20 has substantially the same configuration as that of a lid (not illustrated) of the standardized FOUP that accommodates the wafer W. Accordingly, the lid 20 can seal the front opening of the container body 10 in a state where the substrate-shaped sensor 200 is accommodated in the container body 10. Further, similar to the lid (not illustrated) of the FOUP, the load ports LP1 to LP3 can open and close the lid 20 of the accommodation container 1.

Further, the accommodation container 1 includes a support 30 erected from the inner side of the bottom wall of the container body 10. The support 30 includes a support block 31, support columns 32, a supporting plate 33, and support columns 34. The supporting plate 33 is fixed to the bottom wall of the container body 10 via the support columns 34. The support block 31 is fixed to the supporting plate 33 via the support columns 32. Three support columns 32 are provided, for example, and each have a height adjuster 32a. Accordingly, the height and the levelness of the upper surface of the support block 31 can be adjusted.

With this configuration, when the substrate-shaped sensor 200 is accommodated in the accommodation container 1 and the left and right peripheral edges of the lower surface of the substrate-shaped sensor 200 are supported by the teeth 11, the upper surface of the support block 31 supports a center of the lower surface of the substrate-shaped sensor 200.

Here, a terminal portion 210, with which contact pins 41 to 43, which will be described later, come into contact, is provided in the center of the upper surface of the substrate-shaped sensor 200. In other words, when the substrate-shaped sensor 200 is accommodated in the accommodation container 1, the support block 31 supports the substrate-shaped sensor 200 below the terminal portion 210. Accordingly, even if the terminal portion 210 is pressed by the contact pins 41 to 43, the bend or the like of the substrate-shaped sensor 200 can be prevented.

Further, the support block 31 is formed in a disk shape. Here, a diameter of the disk-shaped support block 31 is formed smaller than the width of the opening of the end effector 120 having a bifurcated shape. Accordingly, when the substrate-shaped sensor 200 is taken out from the accommodation container 1, the end effector 120 of the transfer device (not illustrated) of the loader module LM is inserted below the substrate-shaped sensor 200, but the end effector 120 and the support block 31 do not interfere with each other.

Further, the support 30 disposed inside the accommodation container 1 is preferably formed of, for example, polytetrafluoroethylene (PTFE). Further, the support block 31 being in contact with the back surface of the substrate-shaped sensor 200 is preferably formed of, for example, polytetrafluoroethylene (PTFE). Accordingly, the generation of abrasion powders of the support block 31 due to the friction between the back surface of the substrate-shaped sensor 200 and the upper surface of the support block 31 can be suppressed. Further, the influence of the abrasion powder on the process of the wafer W in the substrate processing chambers PM1 to PM6 can be suppressed.

Further, the accommodation container 1 includes a power feeding mechanism 40 for supplying power to the terminal portion 210 of the substrate-shaped sensor 200. The power feeding mechanism 40 has the contact pins 41 to 43 for making electrical contact with the terminal portion 210 of the substrate-shaped sensor 200. The contact pins 41 to 43 are supported on the lower ends of a shaft member 44 disposed inside the container body 10.

A supporting plate 45 is provided inside the container body 10. As illustrated in FIG. 4, the supporting plate 45 has a substantially C-shape in which a front portion and a center portion are cut out from a disk having the same diameter as that of the wafer W.

The transfer device (not illustrated) of the loader module LM performs a mapping process of detecting the height position of the wafer W (the substrate-shaped sensor 200 accommodated in the accommodation container 1) accommodated in the FOUP. In the mapping process, the distal end of the end effector 120 having an optical sensor at the distal end portion is inserted into the FOUP, and then the end effector 120 is moved in the height direction to detect the wafer W (the substrate-shaped sensor 200). The front portion of the supporting plate 45 is notched to prevent the supporting plate 45 from interfering with the end effector 120 during the mapping process. Further, the center portion of the supporting plate 45 is notched to prevent interference between the shaft member 44 and the supporting plate 45 when the shaft member 44 is elevated.

Further, among the teeth 11 formed in multiple stages, the supporting plate 45 is accommodated in a stage for the supporting plate 45 (the 25th stage from the bottom in the example illustrated in FIG. 3). Further, arc-shaped fixing members 45a are fixed to the left and right peripheral edges of the lower surface of the supporting plate 45 by a bolt or the like (not illustrated). Here, the teeth 11 are sandwiched between the supporting plate 45 and the fixing member 45a. Accordingly, the supporting plate 45 is fixed to the container body 10.

A bracket 45b extending downward is provided on the back surface side of the supporting plate 45. The bracket 45b is provided with an elevation mechanism 46 (a driving mechanism) for elevating the shaft member 44. The elevation mechanism 46 includes a fixing portion 46a, a movable portion 46b, and a rotation portion 46c. The fixing portion 46a of the elevation mechanism 46 is fixed to the bracket 45b. The shaft member 44 is fixed to the movable portion 46b of the elevation mechanism 46 via a bracket 44d. The elevation mechanism 46 includes, for example, a rack and pinion mechanism. Rotating of the rotation portion 46c provided in the fixing portion 46a of the elevation mechanism 46 rotates the pinion and the rotation is converted into a linear motion of the rack fixed to the movable portion 46b, so that the shaft member 44 fixed to the movable portion 46b is lifted and lowered.

Further, a rotation shaft member 47 is connected to the rotation portion 46c of the elevation mechanism 46. One end of the rotation shaft member 47 is fixed to the rotation portion 46c of the elevation mechanism 46, and the other end of the rotation shaft member 47 is provided outside the container body 10 through the rear surface sidewall 10b of the container body 10. Further, a grip gripped by an operator is provided at the other end of the rotation shaft member 47. Further, a seal (not illustrated) for sealing the inside of the container body 10 while allowing the rotation shaft member 47 to rotate is provided between the rotation shaft member 47 and the rear surface sidewall 10b of the container body 10.

Accordingly, rotating of the rotation shaft member 47 outside the container body 10 rotates the rotation portion 46c of the elevation mechanism 46, so that the elevation mechanism 46 can lift and lower the contact pins 41 to 43. In other words, the elevation mechanism 46 can switch between a state where the contact pins 41 to 43 come into contact with the terminal portion 210 of the substrate-shaped sensor 200 (see FIG. 6) and a state where the contact pins 41 to 43 are separated away from the terminal portion 210 of the substrate-shaped sensor 200 (see FIG. 7).

A cover plate 48 is provided at a lower end of the bracket 45b. The cover plate 48 is disposed between the elevation mechanism 46 and the substrate-shaped sensor 200. Accordingly, even if an object drops from the elevation mechanism 46, the dropped object is prevented from falling on the substrate-shaped sensor 200. Further, the cover plate 48 is provided with a through-hole having substantially the same diameter as that of the shaft member 44 (slightly larger than the shaft member 44). The shaft member 44 penetrates the through-hole of the cover plate 48 and is configured to be movable in a penetrating direction.

The shaft member 44, the bracket 44d, the supporting plate 45, the fixing member 45a, the bracket 45b, the elevation mechanism 46, the rotation shaft member 47, and the cover plate 48 disposed inside the accommodation container 1 are preferably formed of a resin composition. For example, the shaft member 44, the bracket 44d, the supporting plate 45, the fixing member 45a, and the bracket 45b are preferably formed of polyacetal (POM). Further, the elevation mechanism 46 is preferably formed of acrylic, polycarbonate, polyacetal, or the like. The rotation shaft member 47 is preferably formed of nylon 6. The cover plate 48 is preferably formed of polyvinylchloride (PVC). Accordingly, materials that may affect the process of the wafer W can be removed from the inside of the accommodation container 1.

As illustrated in FIG. 6, wirings 49a to 49c are provided inside the shaft member 44. Further, the accommodation container 1 includes a DC jack 50 and a switch 60. The wirings 49a to 49c penetrate the rear surface sidewall 10b of the container body 10 from the contact pins 41 to 43 inside the container body 10, and are connected to the DC jack 50 and the switch 60 provided outside the container body 10. A sealing member 49 for sealing the inside of the container body 10 while the wirings 49a to 49c are inserted is provided in the rear surface sidewall 10b of the container body 10. The wiring 49a is, for example, a power feeding line, and one end thereof is connected to the contact pin 41, and the other end thereof is connected to one terminal of the DC jack 50. The wiring 49b is, for example, a ground (GND) line, and one end thereof is connected to the contact pin 42, and the other end thereof is branched, and is connected to the other terminal of the DC jack 50 and the other terminal of the switch 60. The wiring 49c is, for example, a signal line, and one end thereof is connected to the contact pin 43, and the other end thereof is connected to one terminal of the switch 60.

As illustrated in FIGS. 4 and 5, the DC jack 50 is fixed to the rear surface sidewall 10b outside the container body 10. The DC jack 50 has an insertion portion (not illustrated) to which a DC plug of the AC adapter 70 (direct-current power supply) is attached and detached, and two terminals. Further, the AC adapter 70 includes an AC plug and a DC plug. The AC plug of the AC adapter 70 is connected to an AC power source (for example, a commercial power source). The DC plug of the AC adapter 70 is connected to the insertion portion of the DC jack 50. A DC voltage is applied between the contact pin 41 and the contact pin 42 by connecting the AC plug of the AC adapter 70 to the AC power source (for example, the commercial power source) and connecting the DC plug to the insertion portion of the DC jack 50.

As illustrated in FIGS. 4 and 5, the switch 60 is fixed to the rear surface sidewall 10b outside the container body 10. The switch 60 is, for example, a normally open type momentary switch, and can be energized, for example, only while the switch 60 is pressed. That is, when the switch 60 is turned ON, the conduction between the contact pin 43 and the contact pin 42 is enabled, and when the switch 60 is turned OFF, the conduction between the contact pin 43 and the contact pin 42 is blocked.

The grip of the rotation shaft member 47, the DC jack 50, and the switch 60 are provided on the outer side of the rear surface sidewall 10b of the container body 10. Accordingly, for example, a flange (not illustrated) may be provided on the upper surface of the ceiling wall of the container body 10. Further, a handle (not illustrated) or a rail (not illustrated) may be provided on the outer side of the side surface sidewall 10s of the container body 10. Further, a groove (not illustrated) for positioning may be provided on the outer side of the bottom wall of the container body 10. Therefore, the accommodation container 1 accommodating the substrate-shaped sensor 200 can be transferred by a transfer device (not illustrated) such as an overhead hoist transport (OHT) or a person guided vehicle (PGV), similarly to the FOUP accommodating the wafer W.

Here, the transfer device such as the OHT engages with the flange of the accommodation container 1 to hold the accommodation container 1 and transfer the accommodation container 1. Further, the accommodation container 1 held by the OHT rotates around the flange during the transfer. Therefore, the accommodation container 1 transferred by the transfer device such as the OHT or the PGV is required to accommodate the constituent members of the accommodation container 1 in a range of a circular range 300 (illustrated by a two-dot chain line) in a plan view as illustrated in FIG. 4. The grip of the rotation shaft member 47, the DC jack 50, and the switch 60 are provided outside the rear surface sidewall 10b of the container body 10 and in the range 300. Accordingly, even when the accommodation container 1 transferred by the OHT is rotated around the flange, the grip of the rotation shaft member 47, the DC jack 50, and the switch 60, provided outside the container body 10, can be prevented from coming into contact with another component.

The rotation shaft member 47 may penetrate the side surface sidewall 10s of the container body 10, and the sealing member 49 for sealing the inside of the container body 10 while the wirings 49a to 49c are inserted may be provided in the side surface sidewall 10s of the container body 10. Further, the grip of the rotation shaft member 47, the DC jack 50, and the switch 60 may be provided on the outer side of the side surface sidewall 10s of the container body 10. That is, the grip of the rotation shaft member 47, the DC jack 50, and the switch 60 may be provided on the outer side of the side surface sidewall 10s of the container body 10 and in the range 300. Accordingly, even when the accommodation container 1 transferred by the OHT is rotated around the flange, the grip of the rotation shaft member 47, the DC jack 50, and the switch 60, provided outside the container body 10, can be prevented from coming into contact with another component. Further, the grip of the rotation shaft member 47, the DC jack 50, and the switch 60 may be provided on the outer side of one side surface sidewall 10s of the container body 10, or may be separately provided on the outer side of one side surface sidewall 10s and on the outer side of the other side surface sidewall 10s.

Further, as a standard set when transferring the accommodation container (FOUP) by the transfer device such as the OHT or the PGV, the accommodation container (FOUP) is designed in a region of φ480 mm (see a two-dot chain line in FIG. 4). The accommodation container 1 of the present embodiment is designed to accommodate the grip of the rotation shaft member 47, the DC jack 50, and the switch 60 in this region (see the two-dot chain line in FIG. 4).

The DC jack 50 is provided in an orientation in which the DC plug can be inserted from above. Further, the switch 60 is provided in an orientation in which the operation can be performed from above. Accordingly, the operator can insert the DC plug into the DC jack 50 and operate the switch 60 from above, so that the operability is improved.

<Substrate-Shaped Sensor 200>

Next, the substrate-shaped sensor 200 accommodated in the accommodation container 1 will be described with reference to FIG. 8. FIG. 8 is an example of a configuration block diagram of the substrate-shaped sensor 200 accommodated in the accommodation container 1 according to the present embodiment.

The substrate-shaped sensor 200 includes the terminal portion 210, the sensor 220, a sensor controller 230, a storage unit 240, a communication unit 250, a power source controller 260, and a battery 270.

The terminal portion 210 is provided at the center of the upper surface of the substrate-shaped sensor 200. The terminal portion 210 has a terminal array having an arrangement corresponding to the arrangement of the contact pins 41 to 43.

The sensor 220 is a sensor for inspecting the semiconductor manufacturing apparatus 100, and may be, for example, a temperature sensor, an electrostatic capacitance sensor, a humidity sensor, an acceleration sensor, an image sensor, or the like.

The sensor controller 230 controls the sensor 220 to obtain a detection value. Further, the sensor controller 230 controls the storage unit 240 to store the acquired detection value of the sensor 220 in the storage unit 240. Further, the sensor controller 230 controls the communication unit 250 to transmit the detection value of the sensor 220 and/or the detection value of the sensor 220 stored in the storage unit 240 to the outside. Further, the sensor controller 230 can be communicatively connected to an external terminal (not illustrated) via the communication unit 250. Accordingly, by transmitting the control signal from the external terminal to the sensor controller 230, the operation of the sensor controller 230 can be controlled.

The power source controller 260 has a function of determining whether a DC power is in a state of being supplied. In a state where the DC power is being supplied, the power source controller 260 drives the sensor 220, the sensor controller 230, the storage unit 240, and the communication unit 250 with the DC power supply. The power source controller 260 charges the battery 270 with the DC power supply. In a state where the DC power is not being supplied, the power source controller 260 drives the sensor 220, the sensor controller 230, the storage unit 240, and the communication unit 250 with the power supply from the battery 270.

Next, an example of using the accommodation container 1 according to the present embodiment will be described. Here, a case in which the charging function of the substrate-shaped sensor 200 is operated by the accommodation container 1 will be described.

As illustrated in FIG. 6, the substrate-shaped sensor 200 is accommodated in the accommodation container 1. At this time, the front opening of the container body 10 is closed by the lid 20. Specifically, the left and right edge portions of the lower surface of the substrate-shaped sensor 200 are supported by the teeth 11 of the eighth stage, and the center of the lower surface of the substrate-shaped sensor 200 is supported by the support 30 (the support block 31).

The operator inserts the DC plug of the AC adapter 70 into the DC jack 50, and connects the AC plug to the AC power source (the commercial power source).

Next, the operator operates the elevation mechanism 46 to lower the shaft member 44 to allow the contact pins 41 to 43 to come into contact with the terminal portion 210 of the substrate-shaped sensor 200. At this time, the contact pins 41 to 43 press the center of the upper surface of the substrate-shaped sensor 200. Meanwhile, the center of the lower surface of the substrate-shaped sensor 200 is supported by the support 30 (the support block 31). Therefore, the substrate-shaped sensor 200 can be prevented from being bent or damaged. Further, contact pressure between the contact pins 41 to 43 and the terminal portion 210 can be increased.

Accordingly, a charging voltage is applied from the AC adapter 70 to the terminal portion 210 of the substrate-shaped sensor 200 via the DC jack 50, the wirings 49a and 49b, and the contact pins 41 and 42. When the charging voltage is applied to the terminal portion 210, the power source controller 260 starts charging of the battery 270.

The substrate-shaped sensor 200 may be provided with an LED (not illustrated) that indicates the state of the charging of the battery 270. For example, the LED displays the state of the charging of the battery 270 in accordance with a lighting pattern or color. Accordingly, it can be grasped whether the charging function is operating normally from the outside of the accommodation container 1. Further, the state of the charging of the battery 270 can be grasped from the outside of the accommodation container 1.

As described above, according to the accommodation container 1 of the present embodiment, the battery 270 of the substrate-shaped sensor 200 can be charged without taking out the substrate-shaped sensor 200 from the accommodation container 1. Further, the take-out of the substrate-shaped sensor 200 from the accommodation container 1 can prevent moisture or the like from being adsorbed to the substrate-shaped sensor 200. Further, the charging operation by the operator can be simplified.

Further, the sensor 220 or the like is placed on the disk of the substrate-shaped sensor 200. Therefore, the plate thickness of the disk of the substrate-shaped sensor 200 may be thinner than the plate thickness of the wafer W. According to the accommodation container 1 of the present embodiment, the lower surface of the substrate-shaped sensor 200 is supported by the support 30 (the support block 31) when the contact pins 41 to 43 come into contact with the terminal portion 210. Accordingly, the substrate-shaped sensor 200 can be prevented from being bent or damaged.

Further, according to the accommodation container 1 of the present embodiment, the contact pins 41 to 43 come into contact with the terminal portion 210 of the substrate-shaped sensor 200 so as to supply power. When the substrate-shaped sensor 200 accommodated in the accommodation container is wirelessly supplied with power, it is necessary to dispose an antenna (a coil) or the like for power transmission inside the accommodation container. Particles generated from, for example, a material of the antenna for power transmission may affect the process of the wafer W in the substrate processing chambers PM1 to PM6. In contrast, according to the accommodation container 1 of the present embodiment, a material having less effect on the process of the wafer W in the substrate processing chambers PM1 to PM6 can be selected with respect to the material of the member (the support 30, the contact pins 41 to 43, and the shaft member 44) disposed inside the accommodation container 1.

Next, another example of the use of the accommodation container 1 according to the present embodiment will be described. Here, a case where a substrate-shaped sensor 200 accommodated in the accommodation container 1 is operated by an external power source will be described.

As illustrated in FIG. 6, the substrate-shaped sensor 200 is accommodated in the accommodation container 1. At this time, the front opening of the container body 10 is closed by the lid 20. Specifically, the left and right edge portions of the lower surface of the substrate-shaped sensor 200 are supported by the teeth 11 of the eighth stage, and the center of the lower surface of the substrate-shaped sensor 200 is supported by the support 30 (the support block 31).

The operator inserts the DC plug of the AC adapter 70 into the DC jack 50, and connects the AC plug to the AC power source (commercial power source).

Next, the operator operates the elevation mechanism 46 to lower the shaft member 44 to allow the contact pins 41 to 43 to come into contact with the terminal portion 210 of the substrate-shaped sensor 200. Accordingly, a voltage is applied from the AC adapter 70 to the terminal portion 210 of the substrate-shaped sensor 200 via the DC jack 50, the wirings 49a and 49b, and the contact pins 41 and 42.

The operator operates the switch 60. Accordingly, the power source controller 260 is activated. At this time, the sensor 220, the sensor controller 230, the storage unit 240, and the communication unit 250 are driven by an external power source that is applied to the terminal portion 210.

As described above, according to the accommodation container 1 of the present embodiment, the sensor controller 230 of the substrate-shaped sensor 200 can be activated without the take-out of the substrate-shaped sensor 200 from the accommodation container 1. Further, by the external power source driving the sensor controller 230 or the like, the consumption of the charge amount of the battery 270 can be suppressed.

When the sensor controller 230 is activated, for example, information stored in the storage unit 240 can be transmitted to an external terminal (not illustrated) via the communication unit 250. Accordingly, information about the inside of the semiconductor manufacturing apparatus 100 that is detected by the substrate-shaped sensor 200 can be acquired at the external terminal.

Next, still another example of the use of the accommodation container 1 according to the present embodiment will be described. Here, preparations for inspecting the semiconductor manufacturing apparatus 100 by using the substrate-shaped sensor 200 accommodated in the accommodation container 1 will be described.

As illustrated in FIG. 6, the substrate-shaped sensor 200 is accommodated in the accommodation container 1. At this time, the front opening of the container body 10 is closed by the lid 20. Specifically, the left and right edge portions of the lower surface of the substrate-shaped sensor 200 are supported by the teeth 11 of the eighth stage, and the center of the lower surface of the substrate-shaped sensor 200 is supported by the support 30 (the support block 31).

Next, the operator operates the elevation mechanism 46 to lower the shaft member 44 to allow the contact pins 41 to 43 to come into contact with the terminal portion 210 of the substrate-shaped sensor 200.

Next, the operator operates the switch 60. Accordingly, the power source controller 260 is activated. The sensor 220, the sensor controller 230, the storage unit 240, and the communication unit 250 are driven by the power supplied from the battery 270. The sensor controller 230 is communicably connected to an external terminal (not illustrated) via the communication unit 250. When receiving a signal of a recording start instruction via the communication unit 250, the sensor controller 230 starts recording of the detection value detected by the sensor 220. When receiving a signal of a recording end instruction via the communication unit 250, the sensor controller 230 ends the recording of the detection value detected by the sensor 220.

Next, the operator operates the elevation mechanism 46 to lift the shaft member 44 and separates the contact pins 41 to 43 away from the terminal portion 210 of the substrate-shaped sensor 200.

Next, the operator attaches, to the load port LP1, the accommodation container 1 in which the substrate-shaped sensor 200 is accommodated.

The controller 110 controls each component of the semiconductor manufacturing apparatus 100. First, the controller 110 controls the load port LP1 to open the lid 20 of the accommodation container 1, controls the transfer device (not illustrated) of the loader module LM to insert the end effector 120 into the container body 10, and takes out the substrate-shaped sensor 200 (see FIG. 7). Thereafter, the substrate-shaped sensor 200 is transferred to the set position by the transfer device VA of the transfer chamber VTM and the transfer device (not illustrated) of the loader module LM. Then, the substrate-shaped sensor 200 is accommodated in the container body 10, and the lid 20 of the accommodation container 1 is closed.

As described above, according to the accommodation container 1 of the present embodiment, the sensor controller 230 of the substrate-shaped sensor 200 can be activated without the substrate-shaped sensor 200 being taken out from the accommodation container 1. Further, because the sensor controller 230 of the substrate-shaped sensor 200 can be activated immediately before the semiconductor manufacturing apparatus 100 is inspected using the substrate-shaped sensor 200, the consumption of the charge amount of the battery 270 can be suppressed.

Further, similar to the FOUP, the accommodation container 1 may be configured to supply N₂ gas. Accordingly, the substrate-shaped sensor 200 can be accommodated and stored inside the accommodation container 1 in a state where the inside of the accommodation container 1 is filled with the N₂ gas. Accordingly, for example, the various sensors 220 and the like of the substrate-shaped sensor 200 can be prevented from being deteriorated by oxygen or moisture in the atmosphere. Further, the accommodation container 1 may be configured to supply dry air. Accordingly, the substrate-shaped sensor 200 can be accommodated and stored inside the accommodation container 1 in a state where the inside of the accommodation container 1 is filled with the dry air. Accordingly, for example, the various sensors 220 and the like of the substrate-shaped sensor 200 can be prevented from being deteriorated by moisture.

<Other Processing Containers>

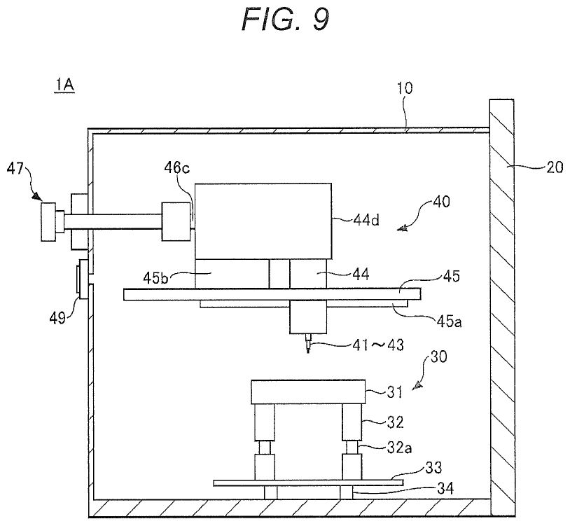

The configuration of the accommodation container 1 is not limited to the configuration of the accommodation container 1 illustrated in FIGS. 2 to 7. Another example of the configuration of the accommodation container 1 will be described with reference to FIG. 9. FIG. 9 is another example of a partial sectional view of an accommodation container 1A as viewed from the side.

In the accommodation container 1 illustrated in FIGS. 2 to 7, the elevation mechanism 46 is disposed below the supporting plate 45. In other words, the elevation mechanism 46 is supported with being suspended from the supporting plate 45. In contrast, in the accommodation container 1A illustrated in FIG. 9, the elevation mechanism 46 is disposed above the supporting plate 45. In other words, the elevation mechanism 46 is placed and supported on the supporting plate 45.

In the accommodation container 1A, the supporting plate 45 is provided with a through-hole having substantially the same diameter as that of the shaft member 44. The shaft member 44 penetrates the through-hole of the supporting plate 45 and is configured to be movable in the penetrating direction. Further, in the accommodation container 1A, the supporting plate 45 also has a function of the cover plate 48 that prevents an object dropped from the elevation mechanism 46 from falling on the substrate-shaped sensor 200.

Other configurations are the same as those of the accommodation container 1 illustrated in FIGS. 2 to 7, and redundant descriptions thereof will be omitted.

Further, a hygroscopic agent accommodation unit (not illustrated) that accommodates a hygroscopic agent may be provided inside the accommodation containers 1 and 1A. Accordingly, the entry of water into the semiconductor manufacturing apparatus 100 via the substrate-shaped sensor 200 can be suppressed.

According to at least one embodiment of the present disclosure, an accommodation container that accommodates a substrate-shaped sensor and a charging method for a substrate-shaped sensor can be provided.

The embodiments disclosed above include, for example, the following aspects.

### (Appendix 1)

An accommodation container that accommodates a substrate-shaped sensor, the accommodation container including:

a container body that has an opening;

a support that is disposed inside the container body and configured to support the substrate-shaped sensor;

a contact pin that is disposed inside the container body and configured to come into contact with a terminal portion of the substrate-shaped sensor;

a driving mechanism that is disposed inside the container body and configured to drive the contact pin;

a rotation shaft member that drives the driving mechanism from an outside of the container body;

a jack that is disposed outside the container body and electrically connected to the contact pin; and

a lid that is configured to close the opening of the container body.

### (Appendix 2)

The accommodation container according to Appendix 1, further including:

a driving mechanism support that is disposed inside the container body and configured to support the driving mechanism.

### (Appendix 3)

The accommodation container according to Appendix 2, in which the driving mechanism support supports the driving mechanism with the driving mechanism being suspended from the driving mechanism support.

### (Appendix 4)

The accommodation container according to Appendix 2, in which the driving mechanism support supports the driving mechanism with the driving mechanism being placed on the driving mechanism support.

### (Appendix 5)

The accommodation container according to any one of Appendices 1 to 4, further including a switch that is disposed outside the container body and electrically connected to the contact pin.

### (Appendix 6)

The accommodation container according to any one of Appendices 1 to 5, in which the terminal portion of the substrate-shaped sensor is provided on an upper surface of the substrate-shaped sensor, and the support includes a support member that supports the substrate-shaped sensor at a back surface position corresponding to a position where the terminal portion of the substrate-shaped sensor is provided.

### (Appendix 7)

The accommodation container according to any one of Appendices 1 to 5, in which the accommodation container is configured to be attached to a load port that is configured such that a carrier that accommodates a substrate is attachable.

### (Appendix 8)

The accommodation container according to any one of Appendices 1 to 7, in which the rotation shaft member penetrates a rear surface sidewall of the container body, the rear surface sidewall being provided on a side opposite to the lid, and the jack is provided on an outer side of the rear surface sidewall

### (Appendix 9)

The accommodation container according to any one of Appendices 1 to 7, in which the rotation shaft member penetrates a side surface sidewall of the container body, and
the jack is provided on an outer side of the side surface sidewall.

### (Appendix 10)

The accommodation container according to 5, in which the rotation shaft member penetrates a rear surface sidewall of the container body, the rear surface sidewall being provided on a side opposite to the lid, and
the jack and the switch are provided on an outer side of the rear surface sidewall.

### (Appendix 11)

The accommodation container according to 5, in which the rotation shaft member penetrates a side surface sidewall of the container body, and
the jack and the switch are provided on an outer side of the side surface sidewall.

### (Appendix 12)

A charging method for a substrate-shaped sensor accommodated in an accommodation container including a container body that has an opening, a support that is disposed inside the container body and configured to support the substrate-shaped sensor, a contact pin that is disposed inside the container body and configured to come into contact with a terminal portion of the substrate-shaped sensor, a driving mechanism that is disposed inside the container body and configured to drive the contact pin, a rotation shaft member that drives the driving mechanism from an outside of the container body, a jack that is disposed outside the container body and electrically connected to the contact pin, and a lid that is configured to close the opening of the container body, the charging method including:

allowing the contact pin to come into contact with the terminal portion of the substrate-shaped sensor by the driving mechanism, and

connecting a direct-current power supply to the jack.

The present invention is not limited to the configurations described herein such as the configurations of the above-described embodiments, and the combinations of these configurations with other elements. Various variations and modifications can be made without departing from the scope of the present invention, and can be adopted according to applications.

What is claimed is:

1. An accommodation container that accommodates a substrate-shaped sensor, the accommodation container comprising:
a container body that has an opening;
a support that is disposed inside the container body and configured to support the substrate-shaped sensor;
a contact pin that is disposed inside the container body and configured to come into contact with a terminal portion of the substrate-shaped sensor;
a driving mechanism that is disposed inside the container body and configured to drive the contact pin;
a rotation shaft member that drives the driving mechanism from an outside of the container body;
a jack that is disposed outside the container body and electrically connected to the contact pin; and
a lid that is configured to close the opening of the container body.

2. The accommodation container according to claim 1, further comprising:
a driving mechanism support that is disposed inside the container body and configured to support the driving mechanism.

3. The accommodation container according to claim 2, wherein
the driving mechanism support supports the driving mechanism with the driving mechanism being suspended from the driving mechanism support.

4. The accommodation container according to claim 2, wherein
the driving mechanism support supports the driving mechanism with the driving mechanism being placed on the driving mechanism support.

5. The accommodation container according to claim 3, further comprising:
a switch that is disposed outside the container body and electrically connected to the contact pin.

6. The accommodation container according to claim 5, wherein
the terminal portion of the substrate-shaped sensor is provided on an upper surface of the substrate-shaped sensor, and
the support includes a support member that supports the substrate-shaped sensor at a back surface position corresponding to a position where the terminal portion of the substrate-shaped sensor is provided.

7. The accommodation container according to claim 6, wherein
the accommodation container is configured to be attached to a load port that is configured such that a carrier that accommodates a substrate is attachable.

8. The accommodation container according to claim 4, wherein
the rotation shaft member penetrates a rear surface sidewall of the container body, the rear surface sidewall being provided on a side opposite to the lid, and
the jack is provided on an outer side of the rear surface sidewall.

9. The accommodation container according to claim 4, wherein
the rotation shaft member penetrates a side surface sidewall of the container body, and
the jack is provided on an outer side of the side surface sidewall.

10. The accommodation container according to claim 5, wherein
the rotation shaft member penetrates a rear surface sidewall of the container body, the rear surface sidewall being provided on a side opposite to the lid, and
the jack and the switch are provided on an outer side of the rear surface sidewall.

11. The accommodation container according to claim 5, wherein
the rotation shaft member penetrates a side surface sidewall of the container body, and
the jack and the switch are provided on an outer side of the side surface sidewall.

12. A charging method for a substrate-shaped sensor accommodated in an accommodation container including a container body that has an opening, a support that is disposed inside the container body and configured to support the substrate-shaped sensor, a contact pin that is disposed inside the container body and configured to come into contact with a terminal portion of the substrate-shaped sensor, a driving mechanism that is disposed inside the container body and configured to drive the contact pin, a rotation shaft member that drives the driving mechanism from an outside of the container body, a jack that is disposed outside the container body and electrically connected to the contact pin, and a lid that is configured to close the opening of the container body, the charging method comprising:
allowing the contact pin to come into contact with the terminal portion of the substrate-shaped sensor by the driving mechanism, and
connecting a direct-current power supply to the jack.
